(19) United States
(12) Patent Application Publication
(10) Pub. No.: US 2006/0255399 A1
(43) Pub. Date: Nov. 16, 2006

(54) Nonvolatile memory device having a plurality of trapping films

(76) Inventors: Ju-Hyung Kim, Yongin-si (KR); Jeong-Hee Han, Suwon-si (KR); Chung-Woo Kim, Suwon-si (KR); Yo-Sep Min, Yongin-si (KR); Moon-Kyung Kim, Yongin-si (KR); Youn-Seok Jeong, Seoul (KR)

Correspondence Address: HARNESS, DICKEY & PIERCE, P.L.C., P.O. BOX 8910, RESTON, VA, 20195, US

(21) Appl. No.: 11/354,076

(22) Filed: Feb. 15, 2006

(30) Foreign Application Priority Data
Feb. 16, 2005 (KR) 10-2005-0012914

(51) Int. Cl. H01L 29/792

(52) U.S. Cl. 257/324

(57) ABSTRACT

Provided is a nonvolatile memory device which includes a tunneling insulating film formed on a semiconductor substrate, a storage node formed on the tunneling insulating film, a blocking insulating film formed on the storage node, and a control gate electrode formed on the blocking insulating film. The storage node includes at least two trapping films having different trap densities, and the blocking insulating film has a dielectric constant greater than that of the silicon oxide film.

### PRIORITY STATEMENT

This application claims the benefit of Korean Patent Application No. 10-2005-0012914, filed on Feb. 16, 2005, in the Korean Intellectual Property Office, the disclosure of which is incorporated herein, in its entirety, by reference.

### BACKGROUND OF THE INVENTION

1. Field of the Invention

The invention is directed to nonvolatile memory devices and methods of fabricating such devices, and more particularly, to nonvolatile memory devices that incorporate a storage node for storing charges and methods of manufacturing memory devices including such storage nodes.

2. Description of the Related Art

During the writing and erasing of data, nonvolatile memory devices may utilize one or more methods including, for example, modifying a threshold voltage transition of a transistor, displacing charge and/or changing a resistance. Those nonvolatile memory devices that utilize the method of modifying a threshold voltage transition typically include a storage node for storing charges and may, therefore, be referred to as charge storing memory devices. Examples of charge storing memory devices include floating gate memory devices that use a floating gate as a storage node and SONOS memory devices that use a charge trapping layer as a storage node.

FIG. 1 is a cross-sectional view of a conventional SONOS type nonvolatile memory device 100 that uses a nitride film 120 as a storage node for trapping charges. A tunnel insulating film, for example, an oxide film 115, through which the tunneling charges or injected hot carriers move is formed between the nitride film 120 and a semiconductor substrate 105, for example, a silicon substrate.

A blocking insulating film, for example, a silicon oxide film 125, is formed between the nitride film 120 and a control gate electrode 130 formed from, for example, polysilicon. The memory device 100 has a conventional SONOS structure in which the oxide film 115, the nitride film 120, and the silicon oxide film 125 are interposed between the semiconductor substrate 105 and the polysilicon 130.

In order to perform a writing operation on the memory device 100 a positive voltage of sufficient magnitude is applied to the control gate electrode 130. In response to the voltage applied to the control gate 130, hot carriers, i.e., electrons, accelerated from the source/drain regions 110 can be injected into the nitride film 120 through the oxide film 115 and/or electrons from the semiconductor substrate 105 can be added to the nitride film 120 by tunneling through the oxide film 115.

Conversely, in order to perform an erasing operation on the memory device 100, a negative voltage of sufficient magnitude is applied to the control gate electrode 130 and/or a positive voltage of sufficient magnitude is applied to the semiconductor substrate 105. In response to the voltage difference between the control gate electrode 130 and the substrate 105 established by the applied voltage(s), electrons previously stored in the nitride film 120 are removed by tunneling into the semiconductor substrate 105 through oxide film 115.

In addition to causing electrons in the nitride film 120 to tunnel into the substrate 105, the voltage difference established during an erasing operation may also induce electrons from the control gate electrode 130 to tunnel through silicon oxide film 125 into the nitride film 120, a phenomenon referred to as “back tunneling.” Accordingly, as the erasing voltage increases, the rate at which electrons are removed from the storage node, i.e., the initial erasing speed, increases, but the likelihood of back tunneling, which will add electrons to the storage node also increases, thereby reducing the efficiency of the erasing operation.

FIG. 2 is a graph illustrating a relationship in a nonvolatile memory device generally corresponding to device 100 of FIG. 1 between a threshold voltage, Vₜₕ, with the device in an erasing state or condition and the variation of the threshold voltage, ΔVₜₕ, of the same device when in a retention state or condition. As illustrated in FIG. 2, the threshold voltage in the erasing state is inversely proportional to the variation in the threshold voltage in the retention state. That is, when Vₜₕ decreases in the erasing state, ΔVₜₕ increases in the retention state. On the contrary, when ΔVₜₕ decreases in the retention state, Vₜₕ increases in the erasing state. In order to increase the erasing efficiency, therefore, Vₜₕ must decrease in the erasing state, and to improve the retention characteristics, ΔVₜₕ must decrease during the retention state.

As illustrated in FIGS. 1 and 2, if the thickness of the oxide film 115 is reduced relative to that of the silicon oxide film 125, the erasing characteristic or performance can be increased by reducing the relative impact of the back tunneling. However, as the thickness of the oxide film 115 is reduced, there will be an increased likelihood that some tunneling of charges from the storage node 120 through the oxide film 115 can occur even without an erasing voltage being applied to the control gate electrode 130, thereby degrading the retention characteristics of the memory device 100. Conversely, as the thickness of the oxide film 115 is increased to suppress movement of electrons through the film, the retention characteristics of the memory device 100 can be improved, but typically such improvements are achieved only at the expense of the writing and/or erasing characteristics which will tend to be degraded.

Similarly, as the trap density of the nitride film 120 increases, the writing and erasing characteristics tend to improve, but the retention characteristic or performance tends to be degraded. Conversely, when the trap density of the nitride film 120 is reduced, the writing (also referred to in the alternative as programming) and the erasing characteristics tend to be degraded, while the retention characteristics tend to improve. Accordingly, improving both the programming and erasing efficiency while improving or maintaining the retention characteristics for semiconductor devices incorporating a structure generally corresponding to that of the device illustrated in FIG. 1 is difficult.

### SUMMARY OF THE INVENTION

The invention provides nonvolatile memory devices and methods of producing such devices that exhibit improved erasing and programming efficiency while also tending to exhibit improved or comparable the retention characteristics.

Nonvolatile memory devices according to one example embodiment of the invention include a tunneling insulating film formed on a semiconductor substrate; a storage node formed on the tunneling insulating film; a blocking insulating film formed on the storage node; and a control gate electrode formed on the blocking insulating film. The storage node may include at least two trapping films having different trap densities and the blocking insulating film may be selected of formed in a manner that produces a dielectric constant that exceeds that of a silicon oxide film.

The trapping films may be stacked between the tunneling insulating film and the blocking insulating film. The trapping film located closer to the blocking insulating film, e.g., the outer trapping film, may have a larger trap density than the trapping layer formed adjacent the tunneling insulating film, e.g., the inner trapping film. The trapping films may be formed of, for example, silicon nitride and/or silicon oxynitride and may be provide or configured as an amorphous film, a polycrystalline film, a nanocrystal, nanoclusters and/or nanodots. The blocking insulating film may be formed from, for example, metal oxides including, for example, one or more of Al₂O₃, HfO₂, ZrO₂ or Ta₂O₅.

Nonvolatile memory devices according to another example embodiment of the invention include a tunneling insulating film formed on a semiconductor substrate; a storage node formed on the tunneling insulating film and comprised of a first trapping film having a first trap density and a second trapping film having a second trap density; a blocking insulating film formed on the storage node and having a dielectric constant greater than that of a silicon oxide film; and a control gate electrode formed on the blocking insulating film.

The second trap density may be greater than the first trap density. The trapping films may be formed from one or more materials including, for example, silicon nitride, silicon oxynitride and/or nanocrystals. The trapping films need not be formed from the same material. For example, the first trapping film may be a silicon nitride film and may be combined with a second trapping film that is a silicon oxynitride film. Similarly, even if the trapping films are formed from similar material, e.g., silicon nitride, the stoichiometry of the films may be modified so that the silicon concentrations are different in the two films.

### BRIEF DESCRIPTION OF THE DRAWINGS

The invention will become more apparent by consideration of the written description below in which example embodiments are detailed with reference to the attached drawings in which:

FIG. 1 is a cross-sectional view of a conventional SONOS type nonvolatile memory device;

FIG. 2 is a graph illustrating a relationship between a threshold voltage in an erasing state and the variation of the threshold voltage in a retention state for a nonvolatile memory device generally according to FIG. 1;

FIG. 3 is a cross-sectional view illustrating a nonvolatile memory device according to an example embodiment of the invention;

FIG. 4 is a graph illustrating the trap density of trapping films of the nonvolatile memory device having a structure generally according to the example embodiment illustrated in FIG. 3;

FIG. 5 is a graph illustrating the connection of energy bands corresponding to the materials and structure of a nonvolatile memory device having a structure generally according to the example embodiment illustrated in FIG. 3;

FIG. 6 is a graph illustrating the magnitude of change of a flat band voltage in a retention state of nonvolatile memory devices having structures generally corresponding to the conventional configuration and the example embodiment illustrated in FIGS. 1 and 3 respectively;

FIG. 7 is a graph illustrating the flat band voltage according to the programming time of the nonvolatile memory devices having structures generally corresponding to the conventional configuration and the example embodiment illustrated in FIGS. 1 and 3 respectively; and

FIG. 8 is a graph illustrating the flat band voltage according to the erasing time of the nonvolatile memory devices having structures generally corresponding to the conventional configuration and the example embodiment illustrated in FIGS. 1 and 3 respectively.

These drawings are provided for illustrative purposes only and are not drawn to scale. The spatial relationships and relative sizing of the elements illustrated in the various embodiments, for example, the various films comprising the memory device and/or gate structures, may have been reduced, expanded or rearranged to improve the clarity of the figure with respect to the corresponding description. The figures, therefore, should not be interpreted as accurately reflecting the relative sizing, value or positioning of the corresponding structural elements that could be encompassed by actual nonvolatile memory devices manufactured according to the example embodiments of the invention.

### DETAILED DESCRIPTION OF THE INVENTION

The invention will now be described more fully with reference to the accompanying drawings in which certain example embodiments of the invention are shown. As will be appreciated by those skilled in the art, however, the invention may be embodied in many different forms and should not be construed as being limited to the embodiments set forth herein. Indeed, these embodiments are provided so that this disclosure will be thorough and complete, and will fully convey the concept of the invention to those skilled in the art.

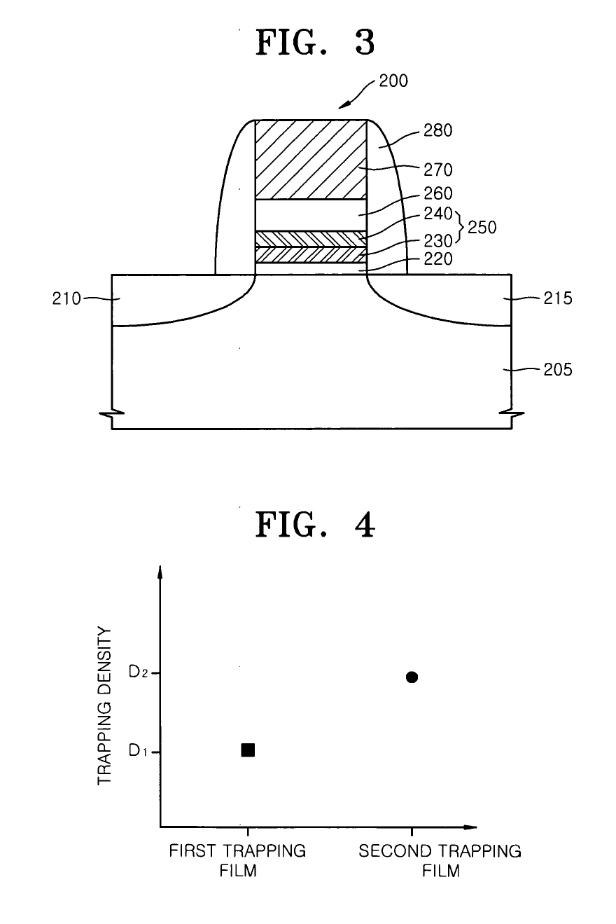

FIG. 3 is a cross-sectional view illustrating a nonvolatile memory device 200 according to an example embodiment of the invention. As illustrated in FIG. 3, the nonvolatile memory device 200 according to this example embodiment of the invention includes a tunneling insulating film 220, a storage node 250, a blocking insulating film 260, and a control gate electrode 270 formed on a semiconductor substrate 205 between source and drain regions 210, 215. More specifically, the tunneling insulating film 220 is formed on the semiconductor substrate 205, and the storage node 250 is formed on the tunneling insulating film 220. The blocking insulating film 260 and the control gate electrode 270 are then sequentially formed on the storage node 250. Optional insulating spacers 280 can also be provided on side walls of the layers 220, 250, 260 and 270 that form the device 200.

The tunneling insulating film 220 is an insulating film, for example, silicon dioxide, into which hot carriers can be injected or through which charges, i.e., electrons, can be tunneled. The tunneling insulating film 220 will typically be provided or incorporated with a thickness that is selected for providing an acceptable balance between both the retention characteristics and writing (also referred to as programming) and erasing characteristics of the memory device 200. As will be appreciated, when the thickness of the tunneling insulating film 220 is reduced, the retention characteristics of the resulting device tend to be degraded to some degree. Conversely, when the thickness of the tunneling insulating film 220 is increased, the retention characteristics tend to improve while the writing and erasing characteristics are tend to be degraded to some degree.

The storage node 250 may include two distinct trapping films, for example, an inner or first trapping film 230 and an outer or second trapping film 240 formed on the first trapping film 230 or an intermediate trapping layer (not shown), with the first and second trapping films 230, 240 having different trap densities. However, in another example embodiment of the invention, the storage node 250 may include more than two trapping films, each of which may exhibit a different trap densities (not shown). Accordingly, although FIG. 3 illustrates only two layers of trapping films, those skilled in the art would be able to prepare structures of more than two trapping layers and adjust the relative trap densities of the layers to achieve a “stepped” or “graduated” series of trap densities corresponding to that of trapping films 230, 240.

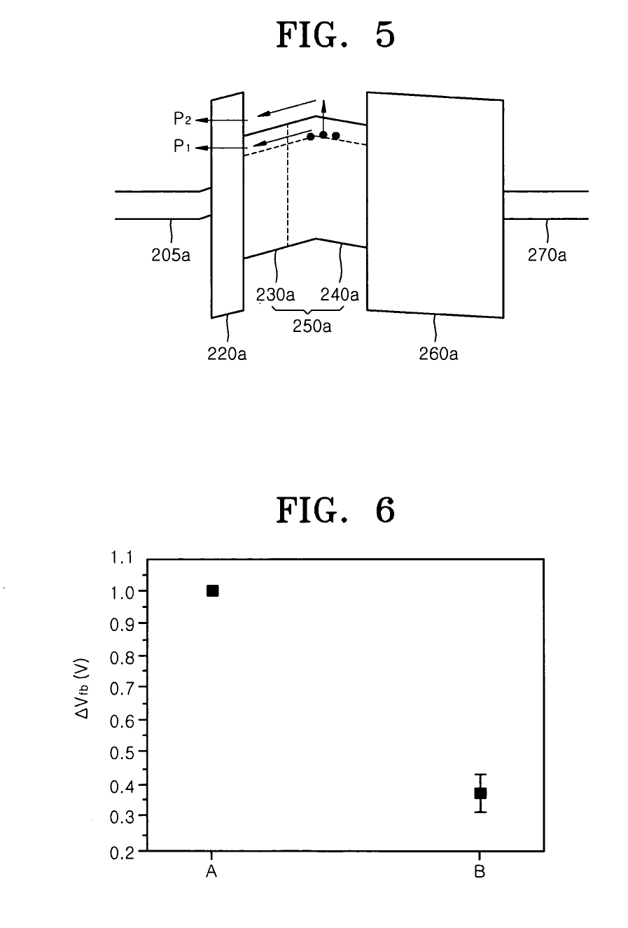

FIG. 6 is a graph illustrating trap density of the trapping films 230 and 240 of the nonvolatile memory device according to device 200 as illustrated in FIG. 5. As illustrated in FIGS. 3 and 4, the first trapping film 230 has a first trap density D₁, and the second trapping film 240 has a second trap density D₂. As depicted in FIG. 4, the second trap density D₂ may be greater than the first trap density D₁. In other words, the second trapping film 240, which is located closer to the blocking insulating film 260 than the first trapping film 230, has a greater trap density than the first trapping film 230, which is located farther from the blocking insulating film than the second trapping film 230.

The first and second trapping films 230 and 240 can be formed from a variety of materials including, for example, silicon nitride and/or silicon oxynitride and may be configured or provided as an amorphous film, a polycrystalline film, a nanocrystal, nanoclusters and nanodots. and/or nanocrystals. In some example embodiments, the first and second trapping films 230 and 240 may be silicon nitride films having different silicon concentrations. Because the trap density is typically proportional to the silicon concentration of the film, the trapping film located closer to the blocking insulating film 260 (i.e., located farther from the substrate 205) tends to have a higher silicon concentration. Accordingly, the second trap density D₂ of the second trapping film 240 can be greater than the first trap density D₁ of the first trapping film 230. In other example embodiments, the first trapping film 230 and the second trapping film 240 may, for example, be formed from a silicon oxynitride film and a silicon nitride film respectively.

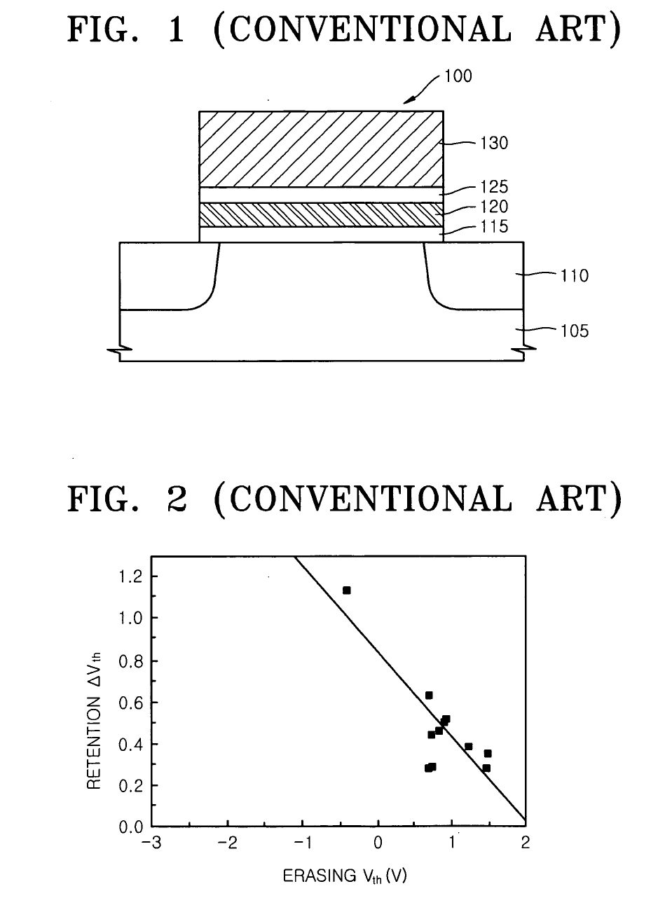

Again, as illustrated in FIG. 1, the blocking insulating film 260 separates the storage node 250 from the control gate electrode 270 and, at the same time, blocks the reverse or back tunneling of charges from the control gate electrode 270 through the blocking insulating film 260 and into the storage node 250. Also, as will be appreciated by those in the art, the composition and thickness of the blocking insulating film 260 will affect the capacitance between the control gate electrode 270 and the semiconductor substrate 205.

In the example embodiment according to the invention, the blocking insulating film 260 has a dielectric constant κ that is greater than that of the silicon oxide film (e.g., greater than about 3.9). That is, the blocking insulating film 260 is formed from an insulating film having “high” dielectric constant for example, a metal oxide selected from a group consisting of, for example, Al₂O₃, HfO₂, ZrO₂ and/or Ta₂O₅. Accordingly, the intensity of an electric field between the storage node 250 and the semiconductor substrate 205 increases, thereby tending to improve the corresponding operational characteristics, for example, the writing and erasing characteristics, of the nonvolatile memory device 200.

As will also be appreciated by those skilled in the art, the thickness of the blocking insulating film 260 can be increased while maintaining the capacitance between the semiconductor substrate 205 and the control gate electrode 270 at an appropriate level. This may be accomplished by incorporating a blocking insulating film 260 having a relatively “high” dielectric constant and adjusting the relative thicknesses of the blocking insulating film and the tunneling insulating film 220 to provide the required degree of capacitance compensation. Accordingly, the erasing efficiency of the nonvolatile memory device 200 can be increased by suppressing the reverse tunneling during the erasing operation.

The control gate electrode 270 can be formed of doped polysilicon, a metal or metal alloy, silicides or a composite film of two or more of these materials. Further, as known to those skilled in the art, the optional spacer insulating films 280 can be formed from a silicon oxide film or a composite film of, for example, a silicon oxide film and a silicon nitride film.

The operation of the nonvolatile memory device having a structure generally corresponding to device 200 as illustrated in FIG. 5 will now be described. The programming or writing operation is performed on the nonvolatile memory device 200 by storing electrons in the storage node 250 by applying a programming voltage, for example, a positive voltage of sufficient magnitude, to the control gate electrode 270. Conversely, the erasing operation is performed on the nonvolatile memory device 200 by moving the electrons stored in the storage node 250 to the semiconductor substrate 205 through application of an erasing voltage, for example, a negative voltage of sufficient magnitude, to the control gate electrode 270.

FIG. 5 is a graph illustrating a relationship between the energy bands of the various layers of material nonvolatile memory device 200 of FIG. 3. As illustrated in FIGS. 3 and 5, the energy bands 205a, 220a, 250a, 260a and 270a correspond, respectively, to the semiconductor substrate 205, the first insulating film 220, the storage node layer 250, the blocking insulating film 260, and the control gate electrode 270 of the nonvolatile memory device 200. The energy band 250a corresponding to the storage node 250 includes both an energy band 230a corresponding to the first trapping film 230 and an energy band 240a corresponding to the second trapping film 240.

An electric field between the storage node 250 and the semiconductor substrate 205 can be induced by applying a voltage between the control gate electrode 270 and the semiconductor substrate 205 of the nonvolatile memory device 200 during the erasing operation. In response to this electrical field, electrons stored in the storage node 250 will tend to move through the tunneling insulating film 220 and into the semiconductor substrate 205.

With the device 200 in the retention state, electrons stored in the storage node 250 may be lost through two electron moving paths P₁ and P₂. First, after moving to a boundary between the tunneling insulating film 220 and the storage node 250 by sequentially moving through trap sites in the storage node 250, electrons move may to the semiconductor substrate 205 by tunneling through the tunneling insulating film 220 (path P₁).

Second, the electrons stored in the storage node 250 may move to the semiconductor substrate 205 by tunneling through the tunneling insulating film 220 after the electrons are excited to an energy level corresponding to the conduction band and are then able to move to the boundary between the tunneling insulating film 220 and the storage node 250 along the conduction band (path P₂). For example, the electrons can be excited to the conduction band energy level when sufficient thermal energy is supplied to the electrons.

The loss of the electrons through the first electron moving path P₁ corresponds to a trap-to-band tunneling path, and the loss of the electrons through the second electron moving path P₂ corresponds to a direct band-to-band tunneling path. Therefore, the leakage or loss of electrons through the first electron moving path P₁ can be affected by the altering the trap density of the storage node 250.

More specifically, rate of loss or leakage of the electrons from the storage node 250 through the first electron moving path P₁ will typically be proportional to the trap density of the storage node. This is because, as the trap density of the storage node 250 increases, the possibility of moving of the electrons in the storage node 250 to the boundary between the storage node 250 and the tunneling insulating film 220 increases.

However, by forming the first or inner trapping film 230 adjacent the tunneling insulating film 220 with a first trap density D₁ that is lower than the overall trap density of the storage node 250, the loss of the electrons through the first electron moving path P₁ can be suppressed. In other words, the possibility that an electron would be able to move through the first trapping film 230 with its first trap density D₁ is reduced even though the electrons may be able to move more easily to the first trapping film through the second trapping film 240 as a result of its relatively higher second trap density D₂.

When the composite or average trap density of the storage node 250 is decreased, the programming (or writing) and erasing speeds will be correspondingly reduced. Therefore, the trap density of the second trapping film 240 can be increased to a level sufficient to provide the desired overall or average trap density and operational performance. Accordingly, the example embodiments of the invention suppress the loss of electrons from the storage node while in the retention state while the programming and erasing speed and/or operational performance of the device can be maintained at levels generally corresponding to or improved upon that obtained with the conventional structure of FIG. 1. The operation speed will be described more in detail below with reference to experimental results.

Also, in another example embodiment of the invention, the storage node 250 can include more than two distinct trapping films (not shown). In such a construction, the trapping film(s) located closer to the blocking insulating film 260 will tend to exhibit a trap density that is higher than the trap density of the trapping layer(s) located farther from the blocking insulating film 260, i.e., closer to the tunneling insulating film 220 and the substrate 205.

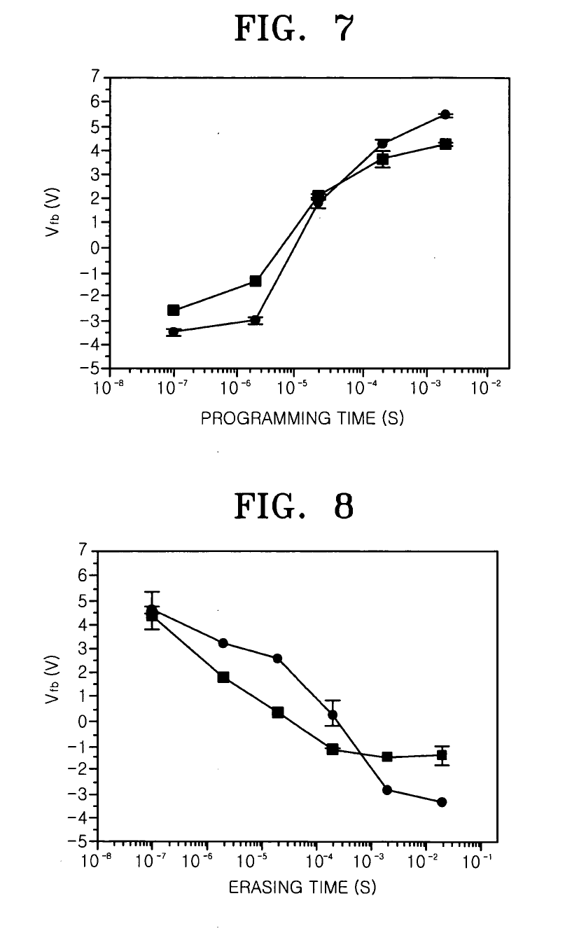

The operation of a nonvolatile memory device corresponding to that illustrated in device 200 will now be described with reference to FIGS. 5 through 7. FIG. 7 is a graph illustrating the magnitude of change of a flat band voltage in a retention state of the nonvolatile memory device A having a construction generally according to FIG. 1 and the nonvolatile memory device B having a construction generally according to FIG. 5. As illustrated in FIG. 7, in the case of the nonvolatile memory device B, the ΔV_{fb} can be reduced to a level less than half of the ΔV_{fb} of the nonvolatile memory device A. The decrease of ΔV_{fb} in the retention state indicates the loss of electrons.

FIG. 7 is a graph illustrating the flat band voltages V_{fb} according to the programming time of a nonvolatile memory device generally corresponding to device 100 as illustrated in FIG. 1 and a nonvolatile memory device generally corresponding to device 200 as illustrated in FIG. 3. As illustrated in FIG. 7, nonvolatile memory devices having a structure generally corresponding to device 200 can exhibit a more rapid change in the flat band voltage V_{fb}, plotted using “●” symbols, compared to the flat voltage V_{fb} of the nonvolatile memory device 100, plotted using “▪” symbols. In the programming operation, the more rapid increase in the flat band voltage V_{fb} indicates that electrons are being stored more rapidly in the storage node 250 and reflects an improvement in the programming operation.

FIG. 8 is a graph illustrating the flat band voltage according to the erasing time of the nonvolatile memory device generally corresponding to device 100 as illustrated in FIG. 1 and the nonvolatile memory device generally corresponding to device 200 as illustrated in FIG. 3. As illustrated in FIG. 8, as with the programming operation shown in FIG. 7, the nonvolatile memory device 200 exhibits a more rapid change in the flat band voltage V_{fb} (again plotted using “●” symbols) when compared to the flat voltage V_{fb} of the nonvolatile memory device 100 (again plotted using “▪” symbols). In the erasing operation, this more rapid decrease in the flat band voltage V_{fb} corresponds to more the rapid erasing or removal of electrons from the storage node 250 and indicates that the erasing operation has been improved.

Again, because the example embodiment illustrated FIG. 3 utilizes the plural trapping layers 230 and 240 having different trap densities, nonvolatile memory devices having a structure generally corresponding to that illustrated in device 200 can provide both improved retention characteristics and improved erasing and programming characteristics at the same time. Also, the programming and erasing characteristics can further be improved by further including a blocking insulating film 260 that exhibits an increased dielectric constant.

While the invention has been particularly shown and described with reference to example embodiments thereof, it will be understood by those of ordinary skill in the art that various changes in form and details may be made therein without departing from the spirit and scope of the invention as defined by the following claims.

What is claimed is:

1. A nonvolatile memory device comprising:
a tunneling insulating film having a first dielectric constant κ₁ formed on a semiconductor substrate;
a storage node formed on the tunneling insulating film;
a blocking insulating film having a second dielectric constant κ₂ formed on the storage node; and
a control gate electrode formed on the blocking insulating film,
wherein the storage node includes at least a first trapping film having a first trap density Dₜ₁ and a second trapping films having a second trap density Dₜ₂ that satisfy the expression Dₜ₁≠Dₜ₂ and
wherein the first and second dielectric constants satisfy the expression κ₂>κ₁.

2. The nonvolatile memory device according to claim 1, wherein:
the tunneling insulating film includes a major portion of silicon dioxide.

3. The nonvolatile memory device according to claim 1, wherein:
the first trapping film is separated from the semiconductor substrate by a first distance d₁ and the second trapping film is separated from the semiconductor substrate by a second distance d₂ whereby the expressions d₁<d₂ and Dₜ₁<Dₜ₂ are both satisfied.

4. The nonvolatile memory device according to claim 2, wherein:
the first and second trapping films each include at least one material independently selected from a group consisting of silicon nitride and silicon oxynitride.

5. The nonvolatile memory device according to claim 3, wherein:
the first trapping film includes silicon nitride having a first silicon concentration C_{Si1}; and
the second trapping film includes silicon nitride having a second silicon concentration C_{Si2} that satisfy the expression C_{Si1}≠C_{Si2}.

6. The nonvolatile memory device according to claim 5, wherein:
the first and second silicon concentrations satisfy the expression C_{Si1}<C_{Si2}.

7. The nonvolatile memory device according to claim 1, wherein:
the blocking insulating film is formed from a material selected from a group consisting of Al₂O₃, HfO₂, ZrO₂ and Ta₂O₅.

8. The nonvolatile memory device according to claim 1, wherein:
the tunneling insulating film consists essentially of silicon oxide.

9. The nonvolatile memory device according to claim 1, further comprising:
a source region and a drain region formed in the semiconductor substrate adjacent opposite edges of the tunneling insulating film.

10. A nonvolatile memory device comprising:
a tunneling insulating film having a first dielectric constant κ₁ formed on a semiconductor substrate;
a storage node formed on the tunneling insulating film and including a plurality of n trapping films including at least an inner trapping film having a first trap density D_{tI} and an outer trapping film having a second trap density D_{tO};
a blocking insulating film formed on the storage node and having a second dielectric constant κ₂ greater than 3.9; and
a control gate electrode formed on the blocking insulating film.

11. The nonvolatile memory device according to claim 10, wherein:
the expression D_{tI}<D_{tO} is satisfied.

12. The nonvolatile memory device according to claim 10, wherein:
the trapping films are each formed from a material independently selected from a group consisting of silicon nitride and silicon oxynitride.

13. The nonvolatile memory device according to claim 10, wherein:
the trapping films each have a structure independently selected from a group including an amorphous film, a polycrystalline film, a nanocrystal, nanoclusters and nanodots.

14. The nonvolatile memory device according to claim 10, wherein:
the first trapping film is a silicon nitride film SiₓN_{y}; and
the second trapping film is a silicon oxynitride film SiₐO_{b}N_{c}.

15. The nonvolatile memory device according to claim 10, wherein:
each of the n trapping films is a silicon nitride film and each of the trapping films has a different silicon concentration C_{Si}.

16. The nonvolatile memory device according to claim 15, wherein:
each of the n trapping films is separated from the semiconductor substrate by a separation distance d and has a silicon concentration C_{Si}, the trapping films being arranged whereby each trapping film has a silicon concentration that is greater than the silicon concentrations of each trapping film having a smaller separation distance.

17. The nonvolatile memory device according to claim 15, wherein:
each of the n trapping films is separated from the semiconductor substrate by a separation distance d, the trapping films being arranged whereby each trapping film has a trap density that is greater than the trap density of each trapping film having a smaller separation distance.

18. The nonvolatile memory device according to claim 10, wherein:
the blocking insulating film is formed of a material selected from a group consisting of Al₂O₃, HfO₂, ZrO₂ and Ta₂O₅.

19. The nonvolatile memory device according to claim 10, further comprising:
a source region and a drain region formed in the semiconductor substrate adjacent opposite edges of the tunneling insulating film.

20. The nonvolatile memory device according to claim 10, wherein:
each of the plurality of n trapping films has trap density that varies by at least 25% from the trap density of each adjacent trapping film.
